(19) United States
(12) Patent Application Publication
(10) Pub. No.: US 2013/0278572 A1
(43) Pub. Date: Oct. 24, 2013

(54) Display Panel and Display Device Having the Same

(71) Applicant: SAMSUNG DISPLAY CO., LTD., YONGIN-CITY (KR)

(72) Inventors: Whee Won Lee, Haeundae-Gu (KR); Jae-Hoon Lee, Seoul (KR)

(73) Assignee: SAMSUNG DISPLAY CO., LTD., YONGIN-CITY (KR)

(21) Appl. No.: 13/771,731

(22) Filed: Feb. 20, 2013

(30) Foreign Application Priority Data
Apr. 20, 2012 (KR) 10-2012-0041328

(51) Int. Cl. G09G 3/36; H03K 17/687; H01L 27/15

(52) U.S. Cl. CPC G09G 3/3648; H01L 27/15; H03K 17/687
USPC 345/204; 257/72; 257/43; 327/109

(57) ABSTRACT

A display panel includes a base substrate, a first gate line, a second gate line, first and second gate pads, a data line, a delay compensating line and a first delay compensating transistor. The first gate line extends in a first direction on the base substrate. The second gate line is substantially parallel to the first gate line. The first and second gate pads extend from first terminals of respective first and second gate lines. The data line extends in a second direction which is different from the first direction. The delay compensating line is substantially parallel to the data line. The first delay compensating transistor is electrically connected to the first and second gate lines and to the delay compensating line.

### CROSS-REFERENCE TO RELATED APPLICATION

This application claims under 35 U.S.C. §119 priority to and the benefit of Korean Patent Application No. 10−2012−0041328, filed on Apr. 20, 2012 in the Korean Intellectual Property Office (KIPO), the entire contents of which are incorporated by reference herein.

### BACKGROUND

1. Technical Field

The present disclosure relates to a display panel and a display device having the display panel, and, more particularly, to a display panel that has a delay compensating circuit.

2. Discussion of the Related Art

A display device typically includes a display panel, a gate driving part that applies a gate driving signal to the display panel and a data driving part that applies a data signal to the display panel. The display panel typically includes gate lines, data lines and switching elements that are electrically connected between a respective gate line and data line.

For the gate driving part, first and second gate driving parts can be electrically connected to each terminal of the gate line, such that the gate driving signal can be applied to each terminal of the gate line. As such, the gate driving part can be considered a dual gate driving part. Thus, the gate driving signal can have enough of a charge transfer period, and would not be RC delayed.

However, the number of gate drive circuits of a gate driving part increases when using the dual gate driving part, such that manufacturing costs increase and the size of a bezel expands.

On the other hand, the gate driving part could be structured to apply the gate driving signal to one terminal of each gate line. As such, the gate driving part may be considered a single gate driving part. However, when the gate driving signal is applied to merely one terminal of the gate line, the gate driving signal may not have enough of a charge transfer period with respect to the load of the gate line and an RC delay may result.

### SUMMARY

Exemplary embodiments of the present invention provide a display panel that has compensation for a charge transfer period of a gate driving signal and for RC delay.

Exemplary embodiments of the present invention also apply to a display device having the display panel.

In an exemplary embodiment a display panel includes a base substrate, a first gate line extending in a first direction on the base substrate, a second gate line substantially parallel with the first gate line, a first and second gate pads extending from respective first terminals of the first and second gate lines, a data line extending in a second direction different from the first direction, a delay compensating line substantially parallel with the data line, and a first delay compensating transistor electrically connected to the first gate line, the second gate line and the delay compensating line.

The first delay compensating transistor may be responsive to a gate driving voltage that is applied to the second gate line, and the first delay compensating transistor may be configured to apply a delay compensating voltage from the delay compensating line to the first gate line.

The first delay compensating transistor may include a first control electrode electrically connected to the second gate line, a first input electrode electrically connected to the delay compensating line, and a first output electrode electrically connected to the first gate line.

The gate driving voltage applied to the second gate line may be synchronized with a falling edge of the gate driving voltage applied to the first gate line.

The delay compensating voltage may be substantially the same as a low-level voltage of the gate driving voltage.

The display panel may further include a dummy gate line substantially parallel with the first and second gate lines, and a second delay compensating transistor electrically connected to the second gate line, the dummy gate line and the delay compensating line.

The display panel may further include a dummy gate pad extending from a first terminal of the dummy gate line.

The delay compensating transistor may include at least one transistor selected from the group consisting of an oxide transistor, a low-temperature polycrystalline silicone transistor and a u-crystalline transistor.

The display panel may further include at least one third gate line between the first gate line and second gate line.

The display panel may further include a fourth gate line substantially parallel with the second gate line, a first dummy gate line substantially parallel with the first, second, third and fourth gate lines, a last gate line substantially parallel with the first dummy gate line, a fifth gate line between the fourth gate line and the last gate line, a second dummy gate line substantially parallel with the first dummy gate line, a second delay compensating transistor electrically connected to the third gate line, the fourth gate line and the delay compensating line, a third delay compensating transistor electrically connected to the fifth gate line, the first dummy gate line and the delay compensating line, and a fourth delay compensating transistor electrically connected to the last gate line, the second dummy gate line and the delay compensating line.

The second delay compensating transistor may include a second control electrode electrically connected to the first dummy gate line, a second input electrode electrically connected to the delay compensating line, and a second output electrode electrically connected to the third gate line. The third delay compensating transistor may include a third control electrode electrically connected to the first dummy gate line, a third input electrode electrically connected to the delay compensating line, and a third output electrode electrically connected to the second gate line.

The display panel may further include a first dummy gate pad extending from a first terminal of the first gate line, and a second dummy gate pad extending from a first terminal of the second dummy gate line.

A second delay compensating transistor may be electrically connected to a second terminal of the second gate line, a third gate line and the delay compensating line.

According to an exemplary embodiment a display device includes a display panel having a base substrate, a first gate line extending in a first direction on the base substrate, a second gate line substantially parallel with the first gate line, a data line extending in a second direction different from the first direction, a delay compensating line substantially parallel with the data line, a delay compensating transistor electrically connected to the first and second gate lines and the delay compensating line, and a gate driving part electrically connected to first terminals of the first and second gate lines.

The display panel may include gate pads electrically connected to the gate driving part, the gate pads extending from the first terminal of the first and second gate lines.

The display device may further include a data driving part configured to apply first and second data voltages to switching elements, respectively, the switching elements connected to the first and second gate lines. The second data line may include a gate line lastly operated, and the data driving part may output the first and second data voltages and a dummy data voltage having substantially a same level as the second data voltage.

The display panel may further include a dummy gate line substantially parallel to the first and second gate lines, a dummy gate pad extending from a first terminal of the dummy gate line, and a second delay compensating transistor electrically connected to the second gate line, a dummy gate line and delay compensate line. The gate driving part may be electrically connected to the dummy gate pad and applies a dummy gate driving signal to the dummy gate pad.

The display panel may further include at least one third gate line disposed between the first gate line and the second gate line.

The display panel may include a first dummy gate line substantially parallel to the first, second and third gate lines, a second dummy gate line substantially parallel to the first gate line, first and second gate pads extending from respective first terminals of the first and second dummy gate lines, a second delay compensating transistor electrically connected to the second gate line, the second dummy gate line and the delay compensating line, and a third delay compensating transistor electrically connected to the second gate line, the second dummy gate line and the delay compensating line. The gate driving part may be electrically connected to the first and second dummy gate pads to output first and second gate operation signals.

According to an exemplary embodiment an apparatus for compensating gate line RC delay in a first gate line of a pair of gate lines of a display device is provided. A delay compensating line is configured to provide a delay compensating voltage. A delay compensating transistor has its control electrode coupled to a second gate line of the pair of gate lines, its input electrode coupled to the delay compensating line, and its drain electrode coupled to the first gate line. A rising edge of a gate driving voltage applied to a second gate line is synchronized with a falling edge of a gate driving voltage applied to the first gate line, such that a falling time of the gate driving voltage applied to the first gate line is reduced when the delay compensating transistor applies the delay compensating voltage to the first gate line in response to the gate driving voltage being applied to the second gate line.

According to exemplary embodiments of the display panel and the display device having the display panel, RC delay of the gate driving signals of the gate lines may be compensated since the display device includes a delay compensating circuit.

The RC delay of the gate driving signal of the last gate line may be compensated since the display device further includes a dummy gate line.

The RC delay of the gate driving signal of the last gate line may be compensated since a data driving part further applies a dummy data voltage.

The degradation of the delay compensating transistor may be prevented since the delay compensating transistor of the delay compensating circuit is driven every frame.

The charge transfer period of the gate driving signal may have enough time since the gate driven signals are driven to overlap with each other.

Thus, reliability of a display device can be improved.

### BRIEF DESCRIPTION OF THE DRAWINGS

Detailed exemplary embodiments of the present invention will now be described with reference to the accompanying drawings, in which:

FIG. 1 is a plan view illustrating a display device according to an exemplary embodiment of the present invention;

FIG. 2 is an enlarged plan view illustrating the display device shown in FIG. 1;

FIG. 3 is a timing diagram illustrating gate driving voltages which are applied to gate lines and a dummy gate driving voltage which is applied to a dummy gate line according to an exemplary embodiment of the present invention;

FIG. 4 is a graph illustrating a relationship between time and a gate driving voltage applied to display devices;

FIG. 5 is a plan view illustrating a display device according to an exemplary embodiment of the present invention;

FIG. 6 is a timing diagram illustrating gate driving voltages which are applied to gate lines and a dummy gate driving voltage which is applied to a dummy gate line according to an exemplary embodiment of the present invention;

FIG. 7 is a graph illustrating a relationship between time and a gate driving voltage applied display devices; and

FIG. 8 is a plan view illustrating a display device according to an exemplary embodiment of the present invention.

### DETAILED DESCRIPTION

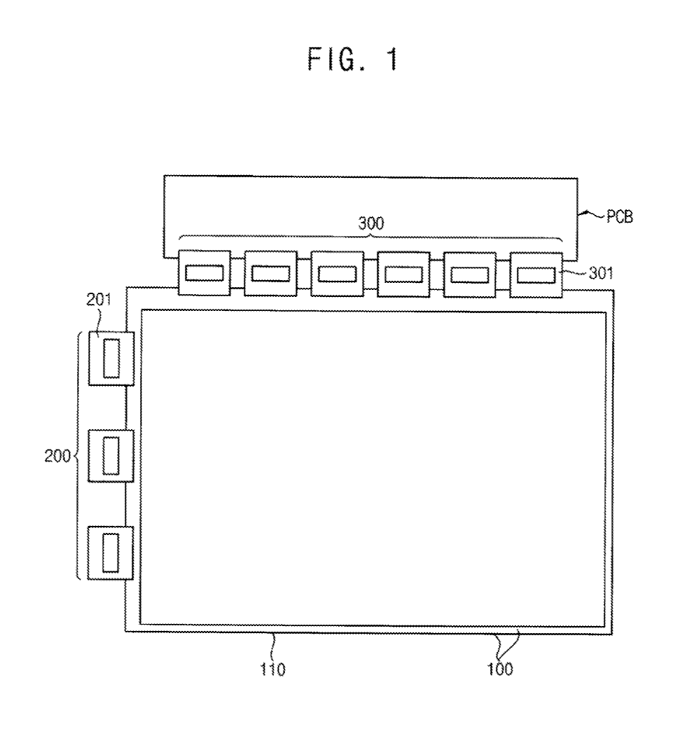

Referring to FIGS. 1 to 3, the display device includes a display panel 100, a gate driving part 200 disposed on an edge of the display panel 100 and a data driving part 300 disposed on another edge of the display panel 100. The display device may further include a printed circuit board (PCB) connected to the data driving part 300.

The display panel 100 includes a display substrate which includes a base substrate 110, a plurality of gate lines GL1, . . . , GL(n−1), GLn disposed on the base substrate 110, a plurality of gate pads GP1, . . . , GP(n−1), GPn, a dummy gate line GLdm, a dummy gate pad GPdm, a plurality of data lines DL1, . . . , DL(m−1), DLm, a plurality of data pads DP1, . . . , DP(m−1), DPm, switching elements and a delay compensating circuit 400, liquid crystal capacitors CLC and storage capacitors CST.

The gate lines GL1, . . . , GL(n−1), GLn and the dummy gate line GLdm extend in a first direction D1. The dummy gate line GLdm is disposed adjacent to gate line GLn of the gate lines GL1, . . . , GL(n−1), GLn.

The gate pads GP1, . . . , GP(n−1), GPn respectively extend from first terminals of the gate lines GL1, . . . , GL(n−1), GLn. The dummy gate pad GPdm extends from a first terminal of the gate line. The gate pad GP1, . . . , GP(n−1), GPn and the gate pad GPdm are electrically connected to the gate driving part 200.

The data lines D1, . . . , D(m−1), Dm extend in a second direction D2 which is different from the first direction D1, that is, substantially perpendicular to direction D1 in an exemplary embodiment.

The data pads DP1, . . . , DP(m−1), DPm extend from the data lines D1, . . . , D(m−1), Dm.

The switching elements SW are electrically connected to the gate lines GL1, . . . , GL(n−1), GLn and the data lines DL1, . . . , DL(m−1), DLm. The liquid crystal capacitors CLS and storage capacitors CST are electrically connected to the switching elements.

The gate driving part 200 includes at least one of the gate driving circuits 201. The gate driving circuit 201 may include an integrated circuit (IC). The gate driving circuit 201 may be in the form of Tape Carrier Package (TCP), Chip on Film (COF), Chip on Glass (COG), and the like.

The gate driving circuit 201 is electrically connected to the first terminal of the gate pads GP1, . . . , GP(n−1), GPn and the first terminal of the gate pad GPdm. In other words, the gate pads GP 1, . . . , GP(n−1), GPn and the dummy gate pad GPdm are input terminals, and the gate driving circuit 201 applies gate driving voltages to the gate lines GL1, . . . , GL(n−1), GLn and a dummy gate driving voltage to the dummy gate line GLdm, in sequence.

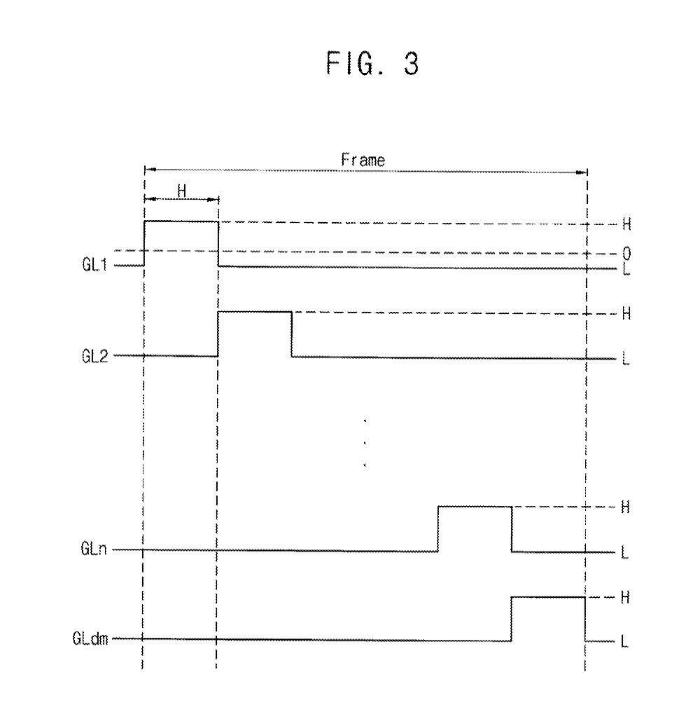

As seen in FIG. 3, the gate driving part applies gate driving voltages and a dummy gate driving voltage, each having a high level voltage H and a low level voltage L, in every horizontal period, in sequence. In an exemplary embodiment, the high level voltage H of the gate driving voltages and the high level voltage H of the dummy gate voltage may be from about 20V to 25V, and the low level voltage L of the gate driving voltages and the low level voltage L of the dummy gate voltage may be from about −5V to −6V.

The data driving part 300 includes at least one data driving circuit 301. The data driving part 300 applies data voltages to first terminals of the data lines DL1, . . . , DL(m−1), DLm.

The delay compensating circuit 400 connected to the second terminals of the gate lines GL1, . . . , GL(n−1), GLn compensates for the delay of the gate lines GL1, . . . , GL(n−1), GLn. The delay compensating circuit 400 includes delay compensating transistors DCTR1, . . . , DCTR(n−1), DCTRn electrically connected to a second terminal of the gate lines and a delay compensating line DCL electrically connected to the delay compensating transistor CDTR1, . . . , DCTR(n−1), DCTRn.

The delay compensating transistors DCTR1, . . . , DCTR(n−1), DCTRn may be one of a oxide transistor, low-temperature polycrystalline silicone (LTPS) transistor and u-crystalline transistor.

The delay compensating transistors DCTR1, . . . , DCTR(n−1), DCTRn compensate each of delays of the gate lines GL1, . . . , GL(n−1), GLn by a delay compensating voltage applied from the delay compensating line DCL. The delay compensating voltage may be substantially identical to a low-level voltage of the gate driving voltages and dummy gate driving voltage. Thus, additional power costs are decreased.

On the other hand, the delay compensating voltage may be lower than a high-level voltage of the gate driving voltages and the dummy gate driving voltage, but may be different from a low-level voltage of the gate driving voltages and the dummy gate driving voltage.

In an exemplary embodiment, a first delay compensating transistor of the delay compensating transistors DCTR1, . . . , DCTR(n−1), DCTRn compensates the gate driving voltage of a first gate line GL1 of the gate lines GL1, . . . , GL(n−1), GLn.

The first delay compensating transistor DCTR1 includes a control electrode CE1 electrically connected to the second gate line GL2, an input electrode SE1 electrically connected to the delay compensating line DCL and a drain electrode DE1 electrically connected to the first gate line GL1.

The first delay compensating transistor DCTR1 applies a delay compensating voltage applied from the delay compensating line DCL to a first gate line GL1 in response to a gate driving voltage applied from the second gate line GL2. Thus, the gate driving voltage of the first gate line GL1 can be compensated.

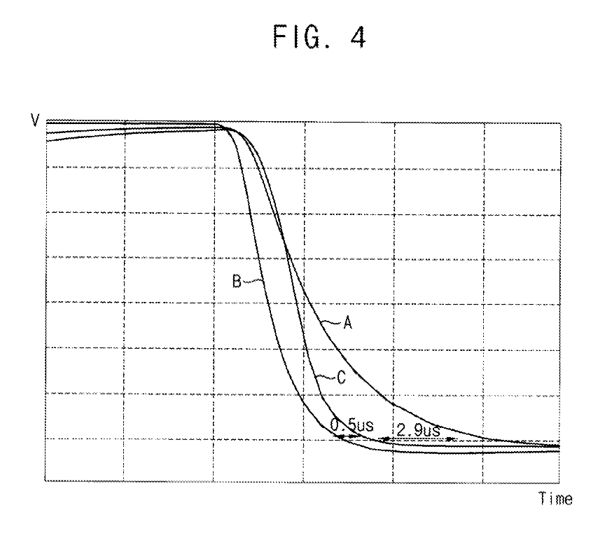

FIG. 4 is a graph illustrating the comparison of gate driving voltages as a function of time as applied to typical display devices and gate driving voltages applied in accordance with an exemplary embodiment of the present invention. Curve ‘A’ depicts a gate driving voltage according to a typical single gate driving part without a delay compensating circuit. Curve ‘B’ depicts a gate driving voltage according to a typical dual gate driving part. Curve ‘C’ depicts a gate driving voltage according to the exemplary embodiment of FIG. 1.

Referring to FIG. 4, the falling time of curve C is shorter than the falling time of curve A by about 2.9 μm, and the falling time of curve C is longer than the falling time of curve B by about 0.5 μm. In other words, the RC delay of a gate driving voltage according to the exemplary embodiment is compensated for such that it is similar to the gate driving voltage according to a dual gate driving part.

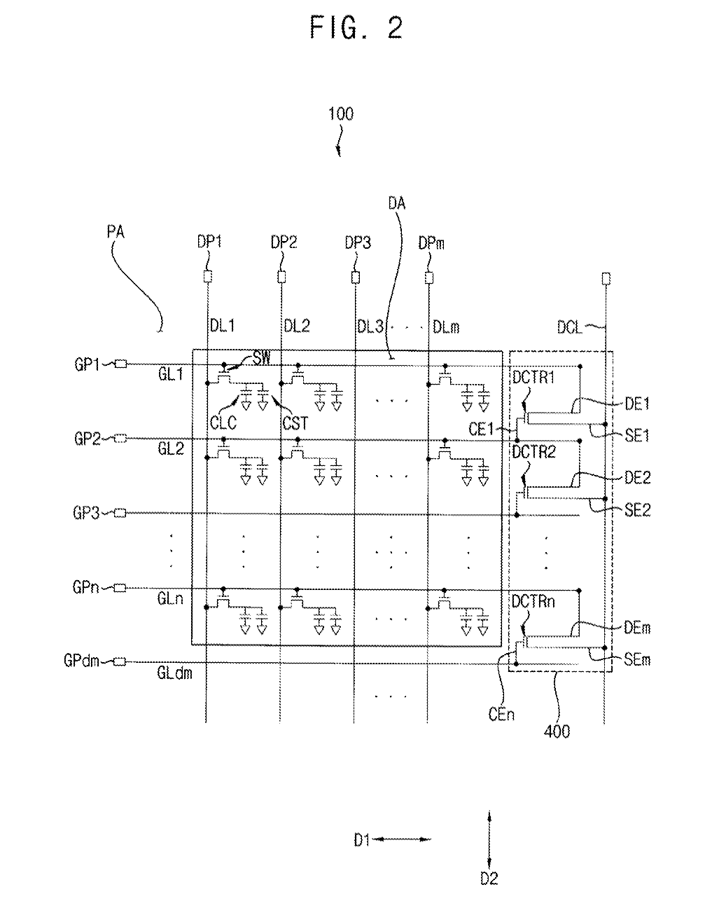

Referring FIGS. 2, 3 and 4, the first delay compensating transistor DCTR1 is connected to a second gate line GL2 to which a gate driving voltage is applied, the gate driving voltage rising to synchronize with a falling edge of a gate driving voltage applied to the first gate line. GL1. Thus, the falling time of a gate driving voltage of the first gate line can be reduced as the first delay compensating transistor DCTR1 applies a delay compensating voltage to the first gate line GL1 in response a high-level voltage of a gate driving voltage applied from the second gate line.

A second or (n−1)th delay compensating transistors DCTR2, . . . , DCTR(n−1) of the delay compensating transistors DCTR1, . . . , DCTR(n−1), DCTRn is compensated by a delay of a gate driving voltage of the second or the (n−1) gate lines.

A second or (n−1)th delay compensating transistor DCTR2, . . . , DCTR(n−1) of the delay compensating transistors DCTR1, . . . , DCTR(n−1), DCTRn is substantially the same structure and function of the first delay compensating transistor DCTR1, such that any repetitive explanation concerning the above elements will be omitted. Thus, a gate driving voltage of the second or (n−1)th gate lines can be similarly compensated.

An nth delay compensating transistor DCTRn of the delay compensating transistors DCTR1, . . . , DCTR(n−1), DCTRn includes a control electrode Cen electrically connected to the dummy gate line GLdm, a input electrode SEn electrically connected to the delay compensating line DCL and a drain electrode DEn electrically connected to the n gate line GLn.

The nth delay compensating transistor DCTRn applies a delay compensating voltage to an nth gate line GLn in response to a high-level voltage of a dummy gate driving voltage applied from the dummy gate line GLdm. Thus, a delay of a gate driving voltage of the n gate line GLn can be compensated.

In other words, the nth delay compensating transistor DCTRn is connected to a dummy gate line GLdm that has a dummy gate driving voltage which is rising when a gate driving voltage of the nth gate line GLn is falling. Thus, the nth delay compensating transistor DCTRn applies a delay compensating voltage to an nth gate line GLn in response to a high-level voltage of a dummy gate driving voltage applied from the dummy gate line GLdm, such that the falling time of a gate driving of the nth gate line can be reduced.

The gate lines GL1, . . . , GL(n−1), GLn, data lines DL1, . . . , DL(m−1), DLm, switching elements SW, liquid crystal capacitors CLC and storage capacitors CST may be disposed on a display area DA of the display panel 100.

The gate pads GP1, . . . , GP(n−1), GPn, the gate line GLdm, the dummy gate pad GPdm, the gate driving part 200, the data driving part 300, delay preventing transistors DCTR1, . . . , DCTR(n−1), DCTRn and a delay preventing line DCL may be disposed on a peripheral area of the display panel 100.

According to an exemplary embodiment, a pth delay compensating transistor may be turned-on in every horizontal period by controlling the (p+1) th gate line, such that the pth delay compensating transistor may prevent gate line signal degradation, p being a natural number which is smaller than n.

Also, a delay of an nth gate line GLn may be compensated under the control the dummy gate line GLdm is increased.

Further, the costs of the display device may be decreased. For example, the width of the bezel may be decreased when the gate driving part disposed on the second terminals of the gate lines GL1, GL(n−1), GLn is removed.

Also, resistance of the electrode of the storage capacitor CST may be decreased by adjusting the width of a common line connected to the storage capacitor CST on the second terminals of the gate lines GL1, GL(n−1), GLn.

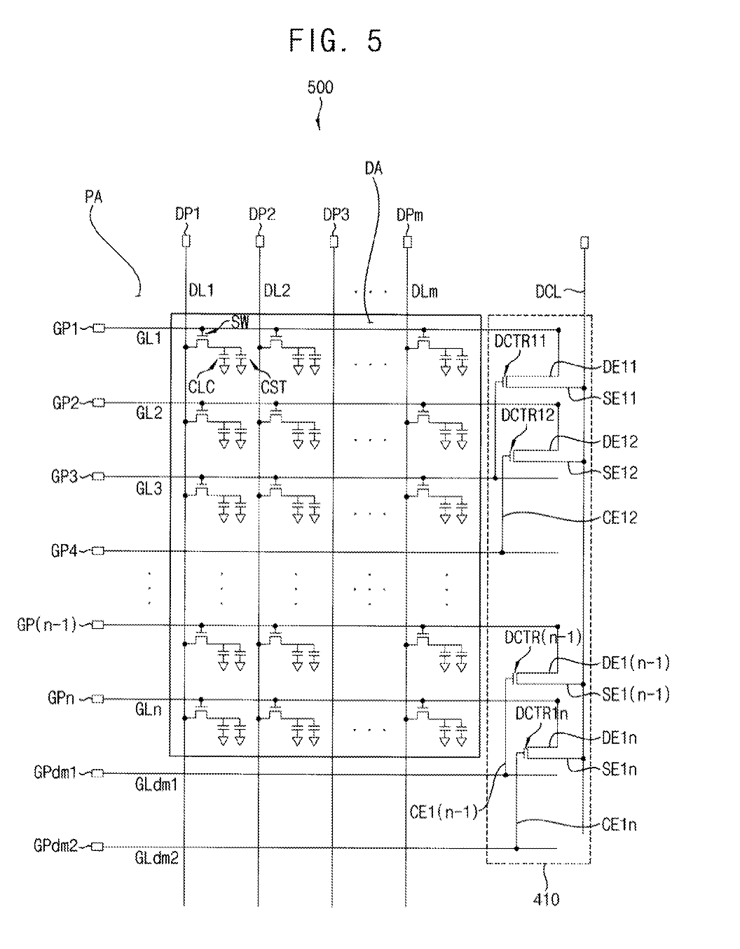

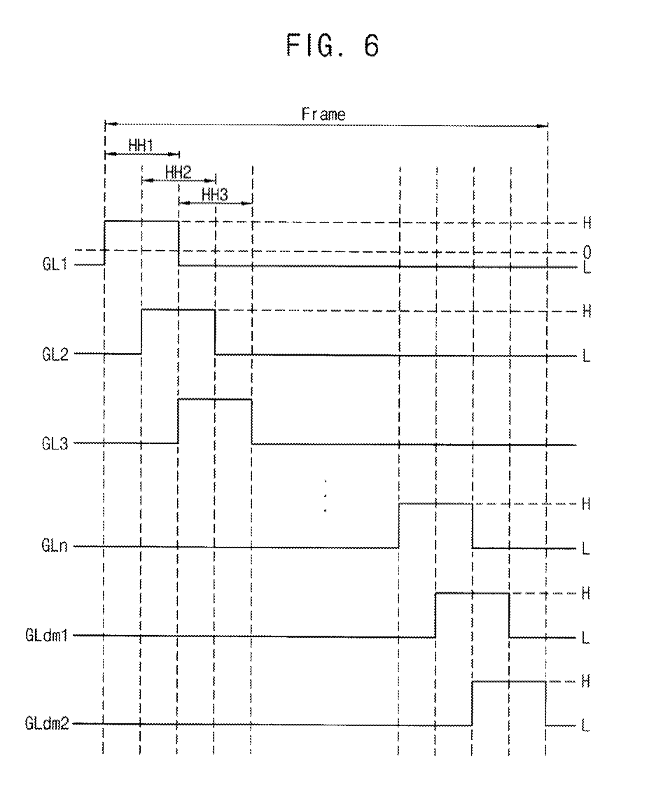

FIG. 5 is a plan view illustrating a display device according to an exemplary embodiment of the present invention. FIG. 6 is a timing diagram illustrating gate driving voltages which are applied to the gate lines and dummy gate driving voltages which are applied to the dummy gate lines in accordance with the exemplary embodiment of the present invention.

The display device according to the exemplary embodiment depicted in FIG. 5 is substantially the same as the display panel according to an exemplary embodiment of FIG. 1, such that any repetitive explanation concerning the above elements will be omitted.

Referring to FIGS. 5 and 6, a display panel 500 of the display device includes a plurality of gate lines GL1, GL(n−1), GLn, a plurality of gate pads GP1, . . . , GP(n−1), GPn, a first dummy gate line GLdm1, a first dummy gate pad GPdm1, a second dummy gate line GLdm2, a second dummy gate pad GPdm1, a plurality of data lines DL1, . . . , DL(m−1), DLm, a plurality of data pads DP1, . . . , DP(m−1), DPm, a display substrate having switching elements SW and a delay compensating circuit 410, liquid crystal capacitors CLC and storage capacitors CST.

The gate lines GL1, . . . , GL(n−1), GLn and the first and second dummy gate lines GLdm1, GLdm2 extend in a first direction D1. The first dummy gate line GLdm1 is disposed adjacent a nth gate line GLn of the gate lines GL1, GL(n−1), GLn and spaced apart from the nth gate line in a second direction D2 which is different direction from the first direction D1. The second dummy gate line GLdm2 is disposed adjacent the first dummy gate line GLdm1 and spaced apart from the first dummy gate line in the second direction D2.

The gate pads GP1, . . . , GP(n−1), GPn respectively extend from first terminals of the gate lines GL1, . . . , GL(n−1), GLn. The first dummy gate pad GPdm1 extends from a first terminal of the first dummy gate line GLdm1. The second dummy gate pad GPdm2 extends from a first terminal of second dummy gate line GLdm2. The gate pads GP1, . . . , GP(n−1), GPn and the first and second dummy gate pads GPdm1, GPdm2 are electrically connected to the gate driving part 200.

A gate driving circuit 201 of the gate driving part 200 is electrically connected to a first terminals of the gate pads GP1, . . . , GP(n−1), GPn and the first terminals of the first and second dummy gate pads GPdm1, GPdm2. In other words, the gate pads GP1, . . . , GP(n−1), GPn and the first and second dummy gate pads GPdm1, GPdm2 are input terminals, and the gate driving circuit 201 applies gate driving voltages to the gate lines GL1, . . . , GL(n−1), GLn and first and second dummy gate driving voltages to the first and second dummy gate lines GLdm1, GLdm2, in sequence.

Horizontal gate driving voltage periods HH1, HH2, HH3 of the gate lines GL1, . . . , GL(n−1), GLn and the first and second dummy gate lines GLdm1, GLdm2 overlap with horizontal gate driving voltage periods for adjacent gate lines. In an exemplary embodiment, a horizontal gate driving voltage period 11112 for a second gate line GL2 overlaps ½ of a horizontal gate driving period for the first gate line GL1, and a horizontal gate driving voltage period HH3 of a third gate line GL2 overlaps ½ of a horizontal gate driving voltage period HH2 for the second gate line GL2. However, the horizontal gate driving voltage period HH3 for the third gate line GL3 does not overlap the horizontal gate driving voltage period HH1 for the first gate line GL1. Thus, a charge transfer period may be increased by two times.

The delay compensating circuit 410 is electrically connected to second terminals of the gate lines GL1, GL(n−1), GLn and compensates the delays of the gate lines GL1, . . . , GL(n−1), GLn. The delay compensating circuit 410 includes delay compensating transistors DCTR11, . . . , DCTR1(n−1), DCTR1n electrically connected to each of the second terminals of the gate lines GL1, . . . , GL(n−1), GLn and a delay compensating line DCL electrically connected to the delay compensating transistors DCTR11, . . . , DCTR1(n−1), DCTR1n.

The delay compensating transistors DCTR11, . . . , DCTR1(n−1), DCTRIn compensates each delay of the gate lines GL1, . . . , GL(n−1), GLn by a delay compensating voltage applied from the delay compensating line DCL.

For example, a first delay compensating transistor DCTR11 of the delay compensating transistors DCTR11, . . . , DCTR1(n−1), DCTR1n compensates the delay of a gate driving voltage of the gate line GL1 of the gate lines GL1, GL(n−1), GLn.

The first compensating transistor DCTR11 includes a control electrode CE11 electrically connected to the third gate line GL3, an input electrode SE11 connected to the delay compensating line DCL and a drain electrode DE11 electrically connected to the first gate line GL1.

The first delay compensating transistor DCTR11 is responsive to a gate driving voltage applied from the third gate line GL3. Thus, the first delay compensating transistor DCTR11 applies a delay compensating voltage to a first gate line GL1. As such, a delay of the gate driving voltage of the first gate line GL1 can be compensated.

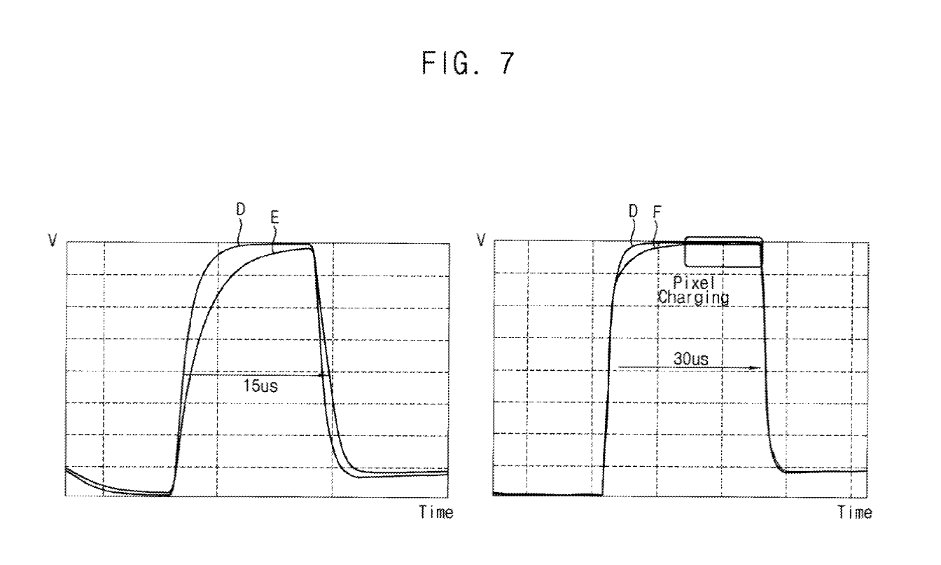

FIG. 7 is a graph illustrating the comparison between gate driving voltages as a function of time applied to typical display devices and gate driving voltages applied in accordance with an exemplary embodiment of the present invention. Curve ‘D’ depicts a gate driving voltage according to a dual gate driving part. Curve ‘E’ depicts a gate driving voltage according to an exemplary embodiment in FIG. 1. Curve ‘F’ depicts a gate driving voltage according to the exemplary embodiment of FIG. 5.

Referring FIG. 7, the charge transfer period of a gate driving voltage according to the dual gate driving part is about 15 μs. However, the charge transfer period of a gate driving voltage according to the exemplary embodiment of FIG. 5 is about 30 μs. In other words, a charge transfer period of a gate driving voltage according to the exemplary embodiment of the present invention is twice the charge transfer period of a gate driving voltage according to the dual gate driving part.

Referring to FIGS. 5, 6 and 7, the first delay compensating transistor DCTR11 is connected to the third gate line GL3. A gate driving voltage is applied to the third gate line GL3. The gate driving voltage synchronizes with a falling edge of a gate driving voltage, such that the gate driving voltage is rising. Thus, the first delay compensating transistor DCTR11 is responsive to a high-level voltage of a gate driving voltage which is applied from the third gate line GL3, such that the first delay compensating transistor DCTR11 applies the delay compensating voltage to the first gate line GL1. Thus, the falling time of the gate driving voltage of the first gate line GL1 is reduced.

Also, horizontal gate driving voltage period HH1 for the first gate line GL1 overlaps ½ of horizontal gate driving voltage period HH2 for the second gate line, such that a charge transfer period of the gate driving voltage is increased by two times. In other words, two of the horizontal gate driving voltage periods for the gate lines GL1, . . . , GL(n−1), GLn according to the exemplary embodiment overlap each other, such that a charge transfer period of the gate driving voltage is increased by two times.

The first compensating transistor DCTR11 is electrically connected to the first and third lines GL1, GL3. A second gate line GL2 is disposed between the first gate line GL1 and third gate line GL3. The second gate line GL2 is not connected to the first delay compensating transistor DCTR11.

A delay of a gate driving voltage of the second or (n−2)th gate lines GL2, . . . , GL(n−3), GL(n−2) is compensated by second or (n−2)th delay compensating transistors DCTR12, . . . , DCTR1(n−3), DCTR1(n−2) of the delay compensating transistors DCTR11, . . . , DCTR1(n−1), DCTR1n.

The structure and function of the second or (n−2)th delay compensating transistors DCTR12, . . . , DCTR1(n−3), DCTR1(n−2) of the delay compensating transistors DCTR11, . . . , DCTR1(n−1), DCTR1n is substantially the same as the first delay compensating transistor DCTR11, such that any repetitive explanation concerning the above elements will be omitted. Thus, the delay of gate driving voltage of the second or (n−1) th gate lines can be compensated.

A (n−1)th delay compensating transistor DCTR1(n−1) of the delay compensating transistors DCTR11, . . . , DCTR1(n−1), DCTR1n includes a control electrode CE1(n−1) electrically connected to the first dummy gate line GLdm1, an input electrode SE1(n−1) electrically connected to the delay compensating line DCL and a drain electrode DE1(n−1) electrically connected to the (n−1)th gate line GL(n−1).

The (n−1)th delay compensating transistor DCTR1(n−1) is responsive to a high-level voltage of a dummy gate driving voltage which is applied from the first gate line GLdm1, such that the (n−1)th delay compensating transistor DCTR1(n−1) applies the delay compensating voltage to the (n−1)th gate line GL(n−1). Thus, the delay of the gate driving voltage of the (n−1)th gate line GL(n−1) may be compensated.

In other words, the (n−1)th delay compensating transistor DCTR1(n−1) is connected to a first gate line GLdm1. A dummy gate driving voltage is applied to the first dummy gate line GLdm1. The dummy gate driving voltage is rising when a gate driving voltage of the (n−1)th gate line is falling. Thus, the (n−1)th delay compensating transistor DCTR1(n−1) is responsive to a high-level voltage of a dummy gate driving voltage which is applied from the first dummy gate line GLdm1. Thus, the (n−1)th delay compensating transistor DCTR1(n−1) applies the delay compensating voltage to the (n−1)th gate line GL(n−1), such that a falling time of the gate driving voltage of the (n−1)th gate line GL(n−1) can be reduced. Also, a charge transfer period of the gate driving voltage may be increased.

The nth delay compensating transistor DCTR1n of the delay compensating transistors DCTR11, . . . , DCTR1(n−1), DCTR1n includes a control electrode electrically connected to the second dummy gate line GLdm2, an input electrode electrically connected to the delay compensating line DCL and a drain electrode electrically connected to the (n−1)th gate line GL(n−1).

The nth delay compensating transistor DCTR1n is responsive to a high-level of a dummy gate driving voltage. The dummy gate driving voltage is applied from the second dummy gate line GLdm2. Thus, the nth delay compensating transistor DCTR1n applies a delay compensating voltage to an nth gate line GLn. The delay compensating voltage is applied from the delay compensating line DCL. Thus, the delay of the gate driving voltage of the nth gate line GLn may be compensated.

In other words, the nth delay compensating transistor DCTR1n is connected to a second gate line GLdm2. A dummy gate driving voltage is applied to the second dummy gate line GLdm2. The dummy gate driving voltage is rising when a gate driving voltage of the nth gate line is falling. Thus, the nth delay compensating transistor DCTR1n is responsive to a high-level voltage of a dummy gate driving voltage which is applied from the first dummy gate line GLdm2. Thus, the nth delay compensating transistor DCTR1n applies the delay compensating voltage to the nth gate line GLn, such that a falling time of the gate driving voltage of the nth gate line GLn can be reduced. Also, a charge transfer period of the gate driving voltage may be increased.

In accordance with the exemplary embodiment of FIGS. 5, 6 and 7, two of the gate driving voltages of the gate line overlap each other, such that the charge transfer period of the gate driving voltage is increased by two times. However, q gate driving voltages of the gate lines may overlap each other, such that the charge transfer period of the gate driving voltages may be increased by q times, q being a natural number, more than 2 and less than n.

According to the exemplary embodiment, driving the gate driving voltage by overlapping them with each other, the charge transfer period of the gate driving voltage may be increased.

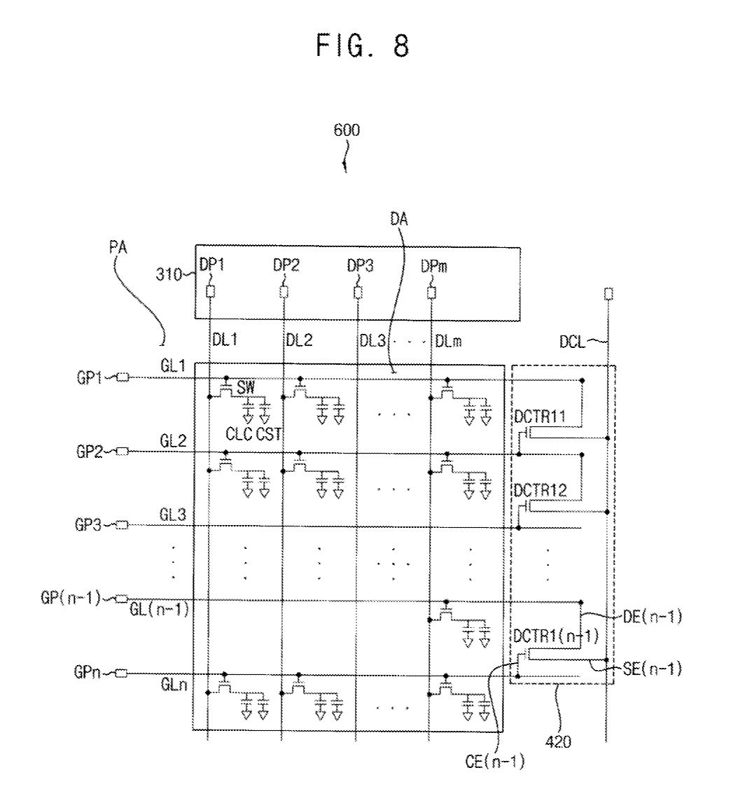

FIG. 8 is a plan view illustrating a display device according to an exemplary embodiment of the present invention.

A display device according to the exemplary embodiment is substantially the same as the display panel according to the exemplary embodiment of FIG. 1, such that any repetitive explanation concerning the above elements will be omitted.

Referring to FIG. 8, a display device includes a display panel 600. A gate driving part 200 (as seen in FIG. 1) is disposed on the first edge of the display panel 600 and a data driving part 310 is disposed on the second edge of the display panel 600.

The display panel 600 includes a display substrate, liquid crystal capacitors CLC and a storage capacitors CST. The display substrate includes a plurality of gate lines GL1, . . . , GL(n−1), GLn, a plurality of gate pads GP1, . . . , GP(n−1), GPn, a plurality of data lines DL1, . . . , DL(m−1), DLm, a plurality of data pads DP1, . . . , DP(m−1), DPm, switching elements SW and a delay compensating circuit 420.

A gate driving circuit 201 (as seen in FIG. 1) of the gate driving part is electrically connected to a first terminals of the gate pads GP1, . . . , GP(n−1), GPn. The gate pads GP1, . . . , GP(n−1), GPn are input electrodes. The gate driving circuit 201 provides an output electrode.

Thus, the gate driving circuit 201 applies gate driving voltages and dummy gate driving voltage to the gate lines GL1, . . . , GL(n−1), GLn, in sequence.

The delay compensating circuit 420 is electrically connected to the gate lines GL1, . . . , GL(n−1), GLn, such that the delay compensating circuit 420 compensates a delay of the first or (n−1)th gate lines GL1, . . . , GL(n−2), GL(n−1) except for the nth gate line GLn. The delay compensating circuit 420 includes first or (n−1) delay compensating transistors DCTR11, . . . , DCTR1(n−2), DCTR1(n−1) which are electrically connected to each of the second terminals of the gate lines GL1, . . . , GL(n−1) and a delay compensating line DCL which is electrically connected to the first or (n−1)th delay compensating transistors DCTR11, . . . , DCTR1(n−2), DCTR1(n−1).

The first or (n−1)th delay compensating transistors DCTR11, . . . , DCTR1(n−2), DCTR1(n−1) compensates each of the first or (n−1)th gate lines GL1, . . . , GL(n−2), GL(n−1) by a delay compensating voltage. The delay compensating voltage is applied from the delay compensating line DCL.

A (n−1)th delay compensating transistor DCTR1(n−1) of the first or (n−1)th delay compensating transistors DCTR11, . . . , DCTR1(n−2), DCTR1(n−1) includes a control electrode CE(n−1) electrically connected to the nth gate line GLn, an input electrode SE(n−1) electrically connected to the delay compensating line DCL and a drain electrode DE(n−1) connected to the (n−1)th gate line GL(n−1).

The (n−1)th delay compensating transistor DCTR1(n−1) is responsive to a high-level of a gate driving voltage applied from the nth gate line GLn. Thus the (n−1)th delay compensating transistor DCTR1(n−1) applies a delay compensating voltage to a (n−1)th gate line GL(n−1). The delay compensating voltage is applied from the delay compensating line DCL. Thus, a delay of the gate driving voltage of the (n−1)th gate line GL(n−1) may be compensated.

The data driving part 310 is electrically connected to a first terminals of the data lines DL1, . . . , DL(m−1), DLm, such that the data driving part 310 applies data voltages and a dummy data voltage to the data lines DL1, . . . , DL(m−1), DLm. In other words, the data driving part 310 may apply m data voltages and the dummy data voltage to the data lines DL1, . . . , DL(m−1), DLm.

Thus, in the display device 600 according to the exemplary embodiment, an nth delay compensating transistor which compensates the nth gate line GLn described in FIGS. 2 and 5 does not exist, such that a gate driving signal which is applied from the nth gate line is distorted. However, the data driving part 310 further applies the continuous dummy data voltage to a data voltage, such that the distortion of the data voltage is prevented. The data voltage is applied to the mth data line DLm.

According to exemplary embodiments of the present invention, a display device may include a delay compensating circuit. Thus, the RC delay of gate driving signals of gate lines may be compensated.

The display device may further include a dummy gate line, such that the RC delay of a gate driving signal of a last gate line may be compensated.

A data driving part may further apply a dummy data voltage, such that the RC delay of a gate driving signal of a last gate line may be compensated.

A delay compensating transistor of the delay compensating circuit may drive at least once in every frame, such that the degradation of the delay compensating transistor may be prevented.

The gate driving signals may be driven to be overlapped, such that, the gate driving signal may have enough charge transfer period.

Thus, reliability of a display device is improved.

The foregoing is illustrative of the present invention and is not to be construed as limiting thereof. Although exemplary embodiments of the present invention have been described, those skilled in the art will readily appreciate that many modifications are possible in the exemplary embodiments without materially departing from the novel teachings and advantages of the present invention. Accordingly, all the exemplary embodiments, and all such modifications, are intended to be included within the scope of the present invention as defined in the following claims.

What is claimed is:

1. A display panel comprises:
a base substrate;
a first gate line extending in a first direction on the base substrate;
a second gate line substantially parallel with the first gate line;
a first and second gate pads extending from respective first terminals of the first and second gate lines;
a data line extending in a second direction different from the first direction;
a delay compensating line substantially parallel with the data line; and
a first delay compensating transistor electrically connected to the first gate line, the second gate line and the delay compensating line.

2. The display panel of claim 1, wherein the first delay compensating transistor is responsive to a gate driving voltage that is applied to the second gate line, and the first delay compensating transistor is configured to apply a delay compensating voltage from the delay compensating line to the first gate line.

3. The display panel of claim 2, wherein the first delay compensating transistor comprises:
a first control electrode electrically connected to the second gate line;
a first input electrode electrically connected to the delay compensating line; and
a first output electrode electrically connected to the first gate line.

4. The display panel of claim 2, wherein the gate driving voltage applied to the second gate line is synchronized with a falling edge of the gate driving voltage applied to the first gate line.

5. The display panel of claim 2, wherein the delay compensating voltage is substantially the same as a low-level voltage of the gate driving voltage.

6. The display panel of claim 1, wherein the display panel further comprises:
a dummy gate line substantially parallel with the first and second gate lines; and
a second delay compensating transistor electrically connected to the second gate line, the dummy gate line and the delay compensating line.

7. The display panel of claim 6, wherein the display panel further comprises a dummy gate pad extending from a first terminal of the dummy gate line.

8. The display panel of claim 1, wherein the delay compensating transistor comprises at least one transistor selected from the group consisting of an oxide transistor, a low-temperature polycrystalline silicone transistor and a u-crystalline transistor.

9. The display panel of claim 1, wherein the display panel further comprises at least one third gate line between the first gate line and second gate line.

10. The display panel of claim 9, wherein the display panel further comprises:
a fourth gate line substantially parallel with the second gate line;
a first dummy gate line substantially parallel with the first, second, third and fourth gate lines;
a last gate line substantially parallel with the first dummy gate line;
a fifth gate line between the fourth gate line and the last gate line;
a second dummy gate line substantially parallel with the first dummy gate line;
a second delay compensating transistor electrically connected to the third gate line, the fourth gate line and the delay compensating line;
a third delay compensating transistor electrically connected to the fifth gate line, the first dummy gate line and the delay compensating line; and
a fourth delay compensating transistor electrically connected to the last gate line, the second dummy gate line and the delay compensating line.

11. The display panel of claim 10,
wherein the second delay compensating transistor comprises:
a second control electrode electrically connected to the first dummy gate line;
a second input electrode electrically connected to the delay compensating line; and
a second output electrode electrically connected to the third gate line, and
wherein the third delay compensating transistor comprises:
a third control electrode electrically connected to the first dummy gate line;
a third input electrode electrically connected to the delay compensating line; and
a third output electrode electrically connected to the second gate line.

12. The display panel of claim 10, wherein the display panel further comprises:
a first dummy gate pad extending from a first terminal of the first gate line; and
a second dummy gate pad extending from a first terminal of the second dummy gate line.

13. The display panel of claim 1, wherein a second delay compensating transistor is electrically connected to a second terminal of the second gate line, a third gate line and the delay compensating line.

14. A display device comprising:
a display panel including:
a base substrate;
a first gate line extending in a first direction on the base substrate;
a second gate line substantially parallel with the first gate line;
a data line extending in a second direction different from the first direction;
a delay compensating line substantially parallel with the data line; and
a delay compensating transistor electrically connected to the first and second gate lines and the delay compensating line; and
a gate driving part electrically connected to first terminals of the first and second gate lines.

15. The display device of claim 14, wherein the display panel comprises gate pads electrically connected to the gate driving part, the gate pads extending from the first terminal of the first and second gate lines.

16. The display device of claim 14, further comprising a data driving part configured to apply first and second data voltages to switching elements, respectively, the switching elements connected to the first and second gate lines,
wherein the second data line includes a gate line lastly operated, and the data driving part outputs the first and second data voltages and a dummy data voltage having substantially a same level as the second data voltage.

17. The display device of claim 14, wherein the display panel further comprises:
a dummy gate line substantially parallel to the first and second gate lines;
a dummy gate pad extending from a first terminal of the dummy gate line; and
a second delay compensating transistor electrically connected to the second gate line, a dummy gate line and delay compensating line, and
wherein the gate driving part is electrically connected to the dummy gate pad and applies a dummy gate driving signal to the dummy gate pad.

18. The display device of claim 14, wherein the display panel further comprises at least one third gate line disposed between the first gate line and the second gate line.

19. The display device of claim 18, wherein the display panel comprises:
a first dummy gate line substantially parallel to the first, second and third gate lines;
a second dummy gate line being substantially parallel to the first gate line;
first and second gate pads extending from respective first terminals of the first and second dummy gate lines;
a second delay compensating transistor electrically connected to the second gate line, the second dummy gate line and the delay compensating line; and
a third delay compensating transistor electrically connected to the second gate line, the second dummy gate line and the delay compensating line, and
wherein the gate driving part is electrically connected to the first and second dummy gate pads to output first and second gate operation signals.

20. An apparatus for compensating gate line RC delay in a first gate line of a pair of gate lines of a display device, the apparatus comprising:
a delay compensating line configured to provide a delay compensating voltage; and
a delay compensating transistor having its control electrode coupled to a second gate line of the pair of gate lines, its input electrode coupled to the delay compensating line, and its drain electrode coupled to the first gate line,
wherein a rising edge of a gate driving voltage applied to a second gate line is synchronized with a falling edge of a gate driving voltage applied to the first gate line, such that a falling time of the gate driving voltage applied to the first gate line is reduced when the delay compensating transistor applies the delay compensating voltage to the first gate line in response to the gate driving voltage being applied to the second gate line.
